(19) United States
(12) Patent Application Publication
(10) Pub. No.: US 2008/0190357 A1
(43) Pub. Date: Aug. 14, 2008

(54) Susceptor for Expitaxial Reactors and Tool for the Handling Thereof

(75) Inventors: Ingemar Karlsson, Rho (IT); Gianluca Valente, Milano (IT); Danilo Crippa, Novara (IT); Franco Preti, Milano (IT)

Correspondence Address: KATTEN MUCHIN ROSENMAN LLP, 575 MADISON AVENUE, NEW YORK, NY, 10022-2585, US

(73) Assignee: LPE S.P.A., Bollate (IT)

(21) Appl. No.: 11/911,412

(22) PCT Filed: Apr. 5, 2006
(86) PCT No.: PCT/EP2006/061318

§ 371 Date: Oct. 12, 2007

(30) Foreign Application Priority Data
Apr. 14, 2005 (IT) MI2005A00645

(51) Int. Cl. C30B 35/00

(52) U.S. Cl. 117/200

(57) ABSTRACT

The present invention relates to a susceptor (3) for epitaxial reactors, comprising a body (31) provided typically with at least one recess (311) for housing substrates on which epitaxial growth is performed; the susceptor (3) comprises a projecting part (32) able to be gripped by a tool (9) so as to be introduced into and extracted from a reaction chamber (12) of an epitaxial reactor.

The present invention relates to a susceptor for epitaxial reactors and to a tool for the handling thereof.

As is known, epitaxial reactors are apparatus designed to treat substrates, often called “slices”, which are used by the microelectronics industry to produce electric components, in particular integrated circuits.

In order to perform this treatment it is required to heat the slices to a high temperature, usually higher than 1,000° C. When the treatment involves the epitaxial deposition of layers of silicon carbide—or “SiC” to use its chemical symbol—the temperature is very high, generally higher than 1,500° C.

The slices are placed on a tray—usually called a “susceptor”—inside a reaction chamber of the epitaxial reactor; the susceptor generally has recesses for housing the slices; there are susceptors provided with one recess only and susceptors provided with a plurality of recesses; there are susceptors with a substantially flat shape and susceptors with a truncated pyramid shape.

There are two categories of epitaxial reactors: those with cold walls and those with hot walls; when the treatment temperature is very high it is very preferable to use hot-wall reactors.

In epitaxial reactors, the heating may be provided by means of lamps via irradiation, resistors via conduction or inducers via electromagnetic induction; the susceptor has the function of supporting and often also the function of heating the substrates.

Usually, the susceptor remains inside the reaction chamber of the reactor and the slices are introduced into the chamber before treatment and are extracted from the chamber after treatment.

In some particular reactors, in particular those which operate at a very high temperature, in particular reactors for the epitaxial growth of layers of silicon carbide, the susceptor with the slices is introduced into the chamber before treatment and is extracted from the chamber after treatment.

In particular in the case of these particular reactors, it is important to have a method which is simple and reliable for introducing the susceptor into the chamber and for extracting the susceptor from the chamber.

The general object of the present invention is to satisfy this requirement.

This object is achieved by means of the susceptor and the tool having the characteristic features described in the accompanying claims.

The idea forming the basis of the present invention is to provide the susceptor with a projecting part able to be easily and reliably gripped by a tool.

According to a further aspect, the present invention also relates to an epitaxial reactor in which the susceptor may be introduced and extracted in an easy and reliable manner.

The present invention will emerge more clearly from the following description to be considered in conjunction with the accompanying drawings in which:

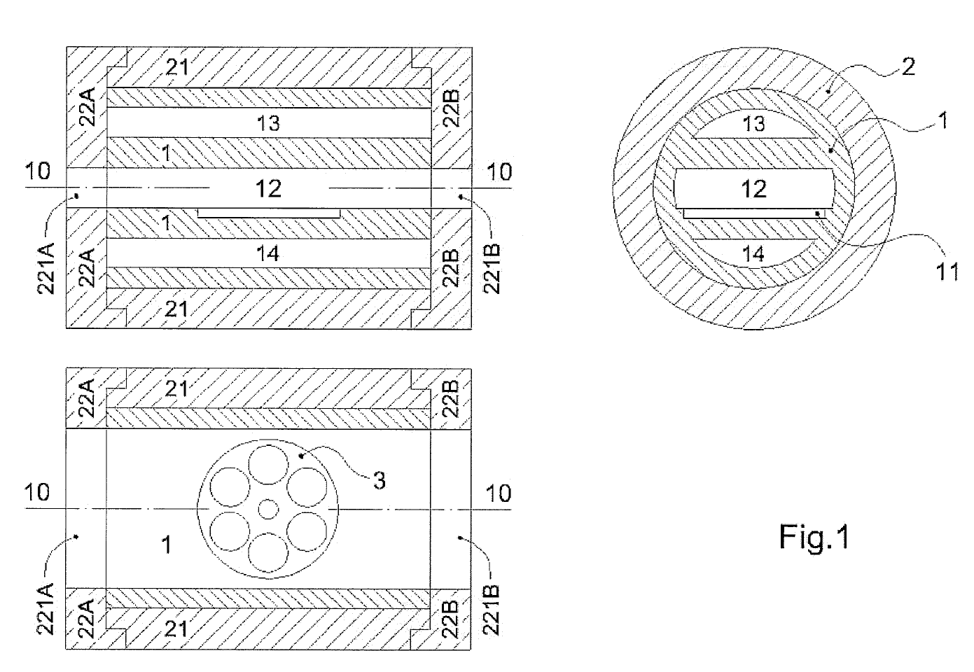

FIG. 1 shows a reaction chamber (surrounded by an insulating jacket) to which the present invention is applicable in particular;

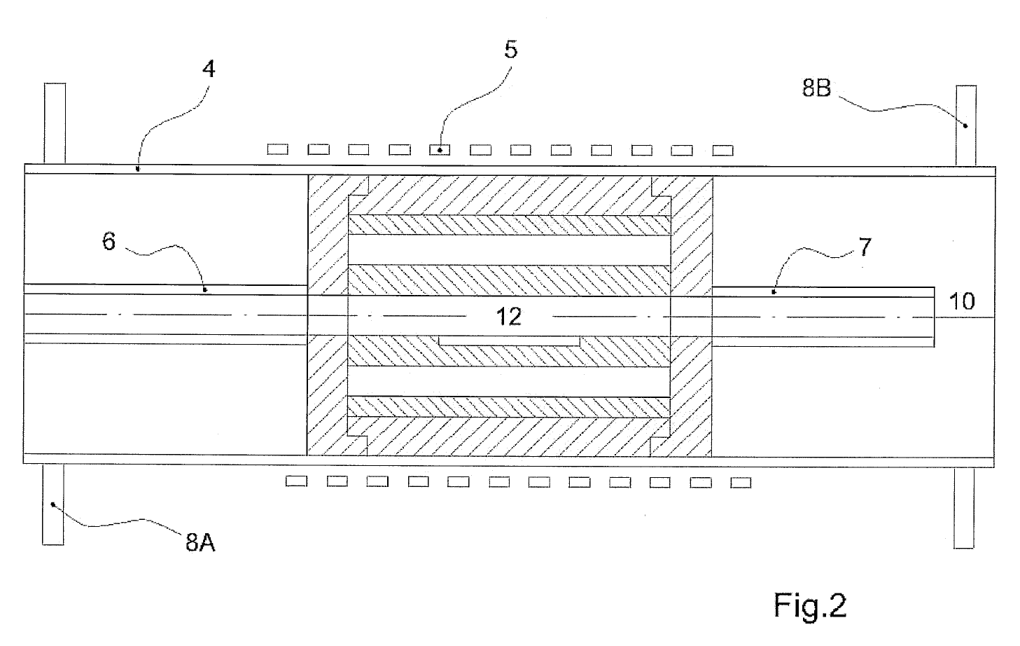

FIG. 2 shows a part of a CVD reactor comprising the assembly according to FIG. 1;

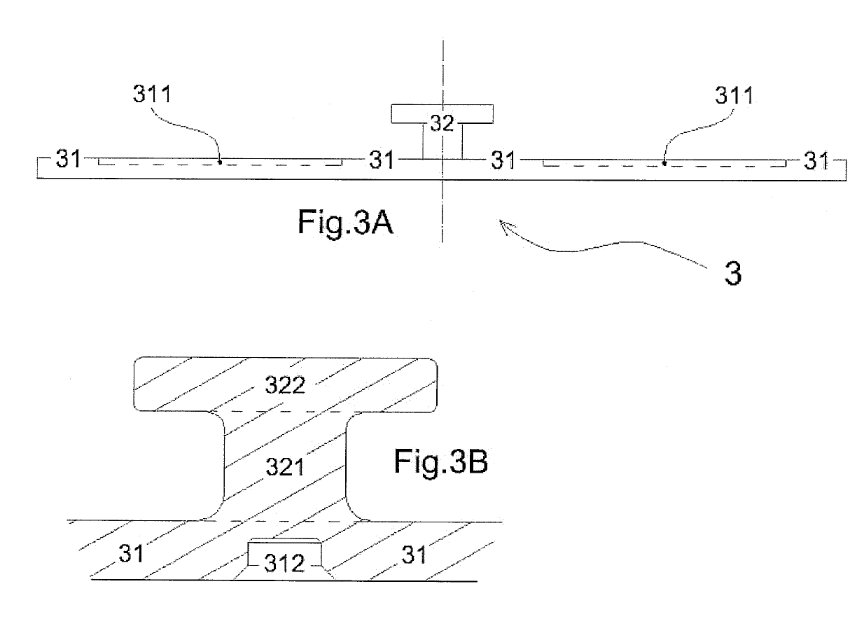

FIG. 3 shows an example of embodiment of a susceptor according to the present invention; and

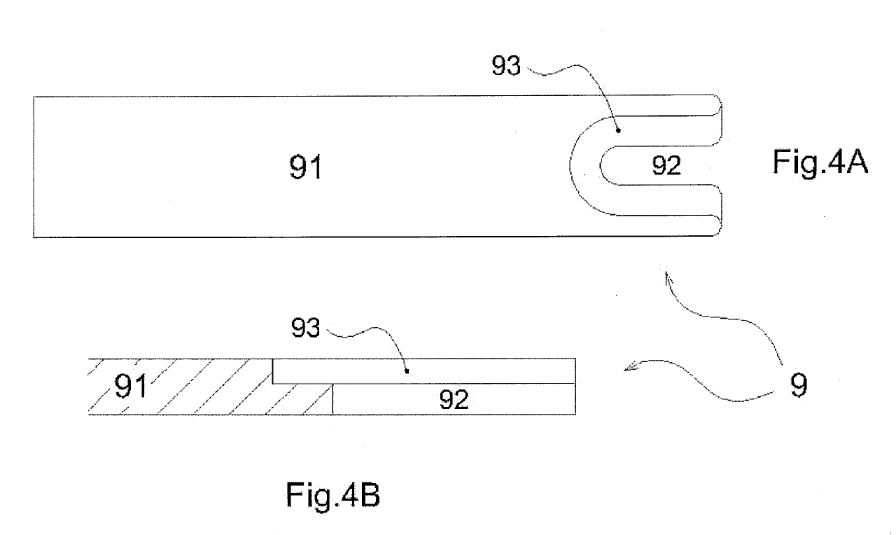

FIG. 4 shows an example of embodiment of a tool according to the present invention.

Both this description and these drawings are to be regarded solely as illustrative and therefore not limiting; moreover, it must be remembered that these figures are schematic and simplified.

FIG. 1 shows the assembly consisting of a reaction chamber, denoted overall by the reference number 1, and a jacket surrounding the latter and denoted overall by the reference number 2.

FIG. 1 shows, on the top right-hand side, a front view of the assembly cross-sectioned centrally, on the top left-hand side, a side view of the assembly cross-sectioned centrally and, on the bottom left-hand side, a view from above of the assembly cross-sectioned centrally.

In the chamber 1 of FIG. 1, the susceptor according to the present invention may be advantageously used, for example; moreover, the tool according to the present invention is particularly useful for introducing/extracting susceptors into/from this chamber or similar chambers.

The chamber 1 is particularly suitable for use in CVD (Chemical Vapour Deposition) reactors for the epitaxial growth of silicon carbide.

The chamber 1 has a cavity 12 able to house substrates on which layers of semiconductor material are deposited; for this purpose, the cavity 12 has a substantially flat bottom wall able to be arranged in a substantially horizontal position inside a CVD reactor; the cavity 12 is surrounded by other walls, in particular by an upper wall and by two side walls. The cavity 12 is able to be passed through longitudinally by reaction gases. The chamber 1 is able to be heated in such a way as to heat the walls of the cavity 12 and therefore also the reaction gases which flow inside it. The chamber 1 is able to be heated by means of electromagnetic induction; for this purpose, the chamber 1 is typically made of graphite and coated with a protective layer of silicon carbide or tantalum carbide. The chamber 1 shown in FIG. 1 extends uniformly along an axis 10 with a length of 300 mm and its cross-section has the external shape of a ring with a diameter of 270 mm; alternatively, this cross-section could have the shape of a polygon or an ellipse. The cross-section of the cavity 12 shown in FIG. 1 has the internal shape substantially of a rectangle with a width of 210 mm and a height of 25 mm.

Chambers similar to that in FIG. 1 may have different dimensions; for example, the width could be between 20 mm and 40 mm and the height could be between 150 mm and 300 mm. The particular feature of these reaction chambers is that of having a width which is much greater than the height (typically by a factor of 7 to 10) and in any case a limited height; therefore, the introduction and the extraction of a susceptor is a problematic operation.

In reaction chambers of the type shown in FIG. 1, the substrates generally rest on a susceptor so as to facilitate loading thereof before the start of the growth process and unloading thereof at the end of the growth process. In the example according to FIG. 1, the susceptor is indicated by the reference number 3 and is able to support six circular substrates inside six corresponding recesses or “hollows”. At the present time, the number of substrates may vary from a minimum of one to a maximum of twelve and their diameter may vary from a minimum of two inches to a maximum of six inches, but this is not relevant for the purposes of the present invention; obviously, with an increase in the number of substrates there is a reduction in their diameter. It is worth noting that the susceptor 3 is shown only in one of the three views of FIG. 1.

In the reaction chambers of the same type as that shown in FIG. 1 it is advantageous to envisage that the substrate support is rotatable so as to favour the uniformity of deposition on the substrates. In the example according to FIG. 1, the susceptor 3 is rotatable even though the means for achieving its rotation have not been shown; various solutions for obtaining rotation of the tray are known to the person skilled in the art, for example from the document WO2004/053189 which is cited herein by way of reference.

In chambers such as that shown in FIG. 1, it is advantageous to envisage that the substrate support is housed inside a recess of the bottom wall of the cavity so that the internal surface of the cavity does not have sudden bumps or dips.

In the example of FIG. 1, the (rotatable) susceptor 3 is substantially in the form of a thin disc with a diameter of 190 mm and thickness of 5 mm and is housed inside a recess 11 of the bottom wall of the cavity 12 with a circular shape.

The substrate support of a chamber such as that shown in FIG. 1 is generally also able to heat the substrates; in fact, it heats mainly as a result of irradiation (produced by the chamber 1, in particular by the walls of the cavity 12) and secondarily as a result of electromagnetic induction; therefore, the susceptor 3 is preferably made, for example, of graphite (material which is a good conductor both of heat and of electric current) and is coated with a protective layer of silicon carbide or tantalum carbide.

The chamber 1 in FIG. 1 has two large through-holes 13 and 14 through which the reaction gases do not pass and inside which substrates are not placed; therefore, these holes are not important for the purposes of the present invention.

Many functional and constructional details relating to a chamber such as that shown in FIG. 1, including the function and the structure of the holes 13 and 14, may be obtained from the documents WO2004/053187 and WO2004/053188 which are cited herein by way of reference.

The reaction chamber of an epitaxial reactor must be physically isolated from the environment which surrounds it in order to control accurately the reaction environment. The reaction chamber of an epitaxial reactor must also be thermally isolated from the environment which surrounds it; in fact, during the epitaxial growth processes, the chamber and its environment are subject to a temperature of between 1000° C. and 2000° C. (depending on the material to be deposited) and it is therefore important to limit the loss of heat; for this purpose, the chamber is surrounded by a thermal insulation structure.

In the example shown in FIG. 1, the chamber 1 is surrounded by a thermal insulating jacket 2; the jacket 2 may be made, for example, of porous graphite, namely a refractory and heat-insulating material; the jacket 2 comprises a cylindrical body 21 and two side covers 22A and 22B, on the left-hand side and right-hand side respectively, which are mounted on the body 21 by means of a peripheral ring which improves the heat insulation of the joining zone of body and cover. The two covers 22A and 22b have two openings 221A and 221B, respectively, with substantially the same cross-section as the cavity 12, for entry of the reaction gases and exit of the exhaust gases, respectively; obviously these openings are substantially aligned with the cavity 12.

These openings are also used for loading and unloading the substrates, or rather in order to introduce and extract the susceptor 3 with the substrates, using suitable tools, in particular using the tool according to the present invention. It is preferable to use only one of the two openings both for loading and for unloading, in particular the opening 221B for exit of the exhaust gases.

FIG. 2 shows a part of a CVD reactor comprising the assembly according to FIG. 1.

The assembly according to FIG. 1 is inserted inside the central zone of a long quartz tube 4, for example two or three or four times the length of the reaction chamber; the function of the tube 4 is, among other things, that of dispersing the radiating energy which is emitted from the side covers 22 and in particular from the openings 221.

An inlet union 6 and an outlet guide 7 are envisaged; these parts are typically made of quartz; the inlet union 6 has the function of joining together a reaction gas supply duct (not shown in FIG. 2), which has a circular cross-section, to the opening 221A of the cover 22A which has a rectangular and very flattened cross-section; the outlet guide 7 has function of guiding the discharge gases towards an exhaust gas discharge duct (not shown in FIG. 2).

A solenoid 5 which generates an electromagnetic field able to heat the chamber 1 by means of electromagnetic induction is wound around the tube 4, in the central zone, near the assembly of FIG. 1.

Two lateral flanges, on the left-hand side 8A and right-hand side 8b, which are typically made of metal and are used to fix the tube to the body of the epitaxial reactor, are provided at the two ends of the tube 4.

As already mentioned, the assembly according to FIG. 2 is particularly suitable for performing the epitaxial growth of silicon carbide since it is particularly suitable for producing and maintaining very high temperatures inside the cavity 12 of the reaction chamber.

FIG. 3 shows a susceptor 3 such as the one inserted inside the reaction chamber of FIG. 1; this susceptor is an example of embodiment of the present invention. At the top there is a side view (FIG. 3A) and on the bottom left there is a cross-sectional view, on a larger scale (FIG. 3B), of its central part.

The susceptor 3 according to FIG. 3 comprises a disc-shaped body 31 and a part 32 which projects from a first side of the body 31. On its first side, the body 31 is provided with six recesses 311 for housing six substrates on which epitaxial deposition can be performed. The part 32 consists of a pin which comprises a shank 321 and a head 322. On a second side of the body 31 there is a cylindrical seat for housing a pin which has the function of guiding the rotation of the susceptor 3.

FIG. 4 shows a tool 9 which may be used in an advantageous manner to introduce/extract the susceptor 3 according to FIG. 3 into/from the cavity 12 of the reaction chamber 1 according to FIG. 1. At the top there is a view from above (FIG. 4A) and at the bottom a cross-sectional view on a larger scale (FIG. 4B) of one of the two ends.

The tool 9 is specifically designed to grip the part 32 of the susceptor 3. It consists of a bar 91 which, at one of its ends (right-hand end in FIG. 4), has a slot 92; the bar 91 is made so that the shank 321 of the pin 32 fits inside its slot 92. Moreover, the bar 91 has a recess 93 along the entire length of the slot 92; the recess 93 is designed so as to receive the head 322 of the pin 32.

The tool 9 according to FIG. 4 is made of quartz; it has a thickness of 8 mm and a width of 45 mm; the slot has a width of 14 mm and the recess has a width of 33 mm and a depth of 4-5 mm. The pin 32 according to FIG. 3 is formed as one piece with the body of the susceptor, is made of graphite and is coated with a layer of tantalum carbide; it has a shank with a diameter of 10 mm and with a height of 10 mm and a head with a diameter of 25 mm and with a height of 5 mm.

In general, the support for substrates according to the present invention comprises a projecting part designed to be gripped by a tool so as to be introduced into and extracted from a reaction chamber of an epitaxial reactor. Obviously, it is possible to envisage more than one projecting part, even though this complicates the structure of the substrate support.

In particular, the substrate support according to the present invention is a susceptor and may be used advantageously in an epitaxial reactor; typically the susceptor comprises a body having at least one recess for housing a substrate on which epitaxial growth is to be performed.

According to its simplest embodiment, the projecting part is a pin.

In order to grip the susceptor easily, it is possible to shape suitably its projecting part. According to one advantageous possibility, the projecting part is a pin which comprises a shank and a head; a first end of the shank is joined to the body and a second end of the shank is joined to the head.

In this case, for the sake of simplicity, both the shank and the head may have the shape substantially of a cylinder and may be substantially coaxial; preferably the diameter of the head is two or three times the diameter of the shank; preferably the height of the shank is two or three times the height of the head. In the example according to FIG. 3, precisely two cylinders according to both these criteria have been used. Alternatively, it would have been possible to use two prisms or a prism and a cylinder; the head could also have, in addition to a cylindrical or prismatic body, one or each end rounded or sunken instead of flat, for example conical or pyramid shaped.

The present invention is applied typically to susceptors having a body which is substantially disc-shaped.

In such a case, it is advantageous to position the projecting part substantially in the centre of the disc; in this way, when the projecting part is gripped by the tool, the susceptor is in equilibrium.

According to the preferred embodiment of the susceptor according to the present invention, all the recesses for the susceptor substrate are positioned on one side of the disc of the susceptor and the projecting part is positioned in the centre on the same side of the disc; in this way, when the projecting part is gripped by the tool, not only is the susceptor in equilibrium, but it also automatically remains in equilibrium.

There are two ways of designing the susceptor with the projecting part according to the present invention.

According to a first constructional possibility, the projecting part is formed as one piece with the body of the susceptor.

According to a second constructional possibility, the projecting part is mounted on the susceptor body, for example by means of screwing or gluing.

As regards the materials to be used for the susceptor according to the present invention, these depend on various factors.

The most typical application of the present invention is in epitaxial reactors with induction heating.

In this case, the body of the susceptor is preferably made of electrically conductive material, preferably graphite; moreover, it is preferable that the projecting part should also be made of electrically conductive material, preferably the same material as the body of the susceptor, preferably graphite.

In many cases, in particular for the epitaxial deposition of silicon or silicon carbide, it is advantageous to coat both the body and the projecting part with a layer of inert and refractory material, preferably silicon carbide (chemical symbol SiC) or tantalum carbide (chemical symbol TaC).

In the case where the projecting part is mounted on the body of the susceptor, it is advantageous for the layers coating the body and the projecting part to be formed after application of the projecting part to the body; in this way, the susceptor consists of two parts, but it may have characteristics similar to those of a susceptor constructed as one piece.

As can be seen from the paragraphs above, the susceptor according to the present invention will frequently be made of graphite. In this case, producing the susceptor as one piece is very costly (because it must be obtained by shaping a large piece of graphite), but provides advantages both because it is more solid and because it is thus more resistant to the physical and chemical agents which are very aggressive inside the reaction chamber of an epitaxial reactor.

It is worth pointing out that, in the case where the susceptor is coated with layer of material, it is preferable for it not to have sharp corners and for the joining radii to be carefully designed so as to be obtained a uniform thickness of the coating layer and limit the thermal and mechanical stresses; moreover, it is important to achieve good adhesion of the coating layer to the underlying material; in the case of graphite coated with tantalum carbide, the problem of adhesion is particularly relevant. In the example of embodiment shown in FIG. 3, all the corners are rounded.

Generally, the tool according to the present invention is specifically designed to grip a projecting part of a susceptor according to the present invention.

This tool may be used manually.

Alternatively, this tool may comprise means for mounting or engagement thereof on the arm of a robot and therefore may be used in an automatic or semi-automatic system for handling susceptors. The tool according to FIG. 4 is designed to be engaged on the arm of a robot and the means mentioned above correspond simply to the left-hand end of the bar 91.

According to a very simple, but very effective example of embodiment, the tool according to the present invention comprises a bar which, at one of its ends, has a slot. Obviously the slot has the function of cooperating with a corresponding part of the susceptor, for example engaging with the shank of the pin underneath the head of the pin as in the case of FIG. 3 and FIG. 4.

In the example according to FIG. 4, the tool consists simply of a bar alone; alternatively, a bar of the type shown in FIG. 4 could form the terminal part of a tool according to the present invention.

The bar according to FIG. 4 is fairly long and fairly thin and therefore may be introduced/extracted easily for example into/from the cavity 12 of the chamber 1 of the reactor according to FIG. 2 with a horizontal translatory movement.

Preferably, at the end where the slot is situated, the bar has a substantially rectangular cross-section; in this case, suitable dimensions of the bar may envisage a width of the bar 3 to 9 times the thickness of the bar and suitable dimensions of the slot may envisage a width of the slot 1 to 3 times the thickness of the bar; the thickness of the bar will typically range between 5 mm and 15 mm depending on its material and the weight of the susceptor which must be handled.

In order to obtain a smaller size engaging area, it is possible to envisage providing the bar with at least one recess along the slot; this recess may be used advantageously to house partially or entirely the head of the pin of the susceptor; this recess may also have the function of ensuring a more reliable engagement. The recess may extend over the entire length of the slot, as in the example of FIG. 4, or may be positioned at the end or in the middle of the slot.

The bar may have advantageously more than one recess for the head of the susceptor pin.

There may be two recesses, for example cylindrical recesses with slightly different diameters, in two positions preferably close to the slot; if the recess has the form of a truncated cone, the susceptor tends to be centred automatically with respect to the recess and therefore with respect to the bar (in the case of slight misalignment) since the head may slide along the side wall of the cone. The two different recesses are useful, for example, since during the growth processes, layers of material are deposited on the head of the pin and increase the dimensions thereof; in this way, the small recess is used when the head is small and the large recess is used when the head is large.

Moreover, it is possible to envisage a first recess which extends over the whole length of the slot and a second recess, which is for example cylindrical or frusto-conical, in an end position or middle position of the slot; the first recess may advantageously be provided with a receiving surface, for example with a conical shape, so that the head of the susceptor pin is able to slide and engage inside the second recess.

The tool according to FIG. 4 is an advantageous example of embodiment; the bar is long, straight and has a flat, rectangular, uniform cross-section, namely it has two long sides and two short sides; the slot is straight and parallel to the length of the bar; the slot intersects the long sides of the cross-section of the bar; the recess extends over the entire length of the slot (from the start to the end both on the right-hand side and on the left-hand side) and also around its terminal end, on only one of the two long sides of the cross-section of the bar.

It may be useful to envisage that the slot of the bar has a receiving surface at its front end, namely at its inlet; in this way, for example, it will be easier to insert the shank of the susceptor pin into the slot and moreover it will be possible to compensate for slight misalignment between the slot and shank.

As an alternative to or in addition to the receiving surface at the inlet of the slot, it is possible to envisage that the width of the slot is quite larger than the diameter of the shank so as to compensate for slight misalignment between slot and shank and avoid (or at least limit) contact between tool and shank of the susceptor.

The tool according to the example in FIG. 4 has nearly all rounded corners; this is useful in particular in those parts which may come into contact with the susceptor, in particular with the shank and with the head of the pin, so as to avoid (or at least limit) scratching of the surface of the susceptor by the tool.

The tool could envisage an articulation having preferably the possibility of limited rotation, preferably less than 10°; in the case of the bar, the articulation could be positioned in a middle position thereof, for example close to the end where the susceptor is gripped; in this way it will be easier to grip the susceptor, in particular insert the shank of the pin into the slot and compensate for slight misalignment between tool and susceptor. The articulation may advantageously be combined with the receiving surface at the inlet of the slot.

As mentioned, the tool according to the present invention has the function of gripping a susceptor, designed typically for epitaxial reactors, in order to introduce it into and extract it from the reaction chamber.

Generally, the tool extracts the susceptor with the substrates grown at a temperature ranging from 200° C. to 400° C. and the slices are left to cool outside of the reaction chamber. Generally, the susceptor with the substrates to be grown is introduced at room temperature, typically from 15° C. to 30° C.

The bar of the tool may be made of metal or a non-metallic material or, in any case, a material which is particularly resistant and retains a sufficient rigidity at the temperatures mentioned above.

As regards the non-metallic materials, the preferred material is quartz which is not only very refractory, but also very inert; moreover, it has a fairly low cost.

As regards the metals, the preferred material is stainless steel; among the various stainless steels, an optimum choice consists in steels based on iron and characterized by a chrome content of 16-18%, nickel content of 10-14%, molybdenum content of 2-4% and carbon content less than 0.08%.

In order to make the stainless steel tool more refractory it is useful to envisage a coating layer; for this purpose, it is possible to use oxides, for example vanadium oxide or titanium oxide or zirconium oxide or tungsten oxide; alternatively, it is possible to use nitrides or carbides, for example of the same metals. This coating layer may be obtained advantageously by means of PVD (Physical Vapour Deposition).

It is also possible to envisage coating the steel tool with a layer of PTFE (polytetrafluoroethylene) or PEEK (polyetheretherketone) or similar materials, if the susceptor is not handled at temperatures which are too high.

The susceptor and the tool according to the present invention, as described above and claimed below, are suitable for use in an epitaxial reactor and, in particular, in an epitaxial reactor with heating of the susceptor by means of electromagnetic induction.

According to a particular aspect, the present invention also relates to an epitaxial reactor; this is characterized in that it comprises such a susceptor and such a tool. Moreover, it may also comprise a robot equipped with an arm on which the tool according to the present invention is mounted or engaged.

This reactor may be advantageously equipped with an automatic or semi-automatic system for handling susceptors; in this case it will comprise an electronic control system able to control the robot so as to grip the projecting part of the susceptor by means of the tool.

The susceptor and the tool according to the present invention, as described above and claimed below, are particularly suitable and advantageous for being used in an epitaxial reactor with a long, wide, low reaction chamber heated by means of electromagnetic induction such as that, for example, shown in FIG. 2.

According to a preferred embodiment of the reactor according to the present invention, this comprises a reaction chamber having a substantially rectangular inlet with a height ranging between 20 mm and 40 mm; the electronic control system is able to control the movement of the robot so as to grip the projecting part of the susceptor, release the projecting part of the susceptor, introduce the susceptor into the reaction chamber and extract the susceptor from the reaction chamber; preferably, the inlet of the reaction chamber has a width ranging between 150 mm and 300 mm and the disc of the susceptor has a diameter 20-40 mm less than the width of the inlet.

With reference to FIG. 1 and FIG. 2, during loading of the substrates, the following operations are performed: a long horizontal translatory movement in order to introduce the susceptor 3 into the cavity 12, a short vertical translatory movement downwards in order to deposit the susceptor 3 into the recess 11 and release it, and a long vertical translatory movement in order to extract the tool 9; and, during unloading of the substrates, a long horizontal translatory movement in order to introduce the tool 9 into the cavity 12, a short vertical translatory movement upwards in order to grip the susceptor 3 and raise it from the recess 11, and a long vertical translatory movement in order to extract the susceptor 3.

It is not easy, during loading and unloading, to obtain a perfect alignment between susceptor, recess of the cavity and tool. In order to compensate for slight misalignment between susceptor and tool, it is possible to envisage suitable dimensions and/or suitable shaping of the bar, in particular its slot and/or its recess. In order to compensate for slight misalignment between susceptor and recess of the cavity, it is possible to envisage that the recess of the cavity has flared edges and/or that the pin for guiding rotation has its upper end flared and/or the seat of the rotation guiding pin has its inlet opening flared.

What is claimed is:

1-22. (canceled)

23. Susceptor (3) for epitaxial reactors, comprising a body (31) provided typically with at least one recess (311) for housing substrates on which epitaxial growth is to be performed, characterized in that it comprise a projecting part (32) able to be gripped by a tool (9) so as to be introduced into and extracted from a reaction chamber (12) of an epitaxial reactor.

24. Susceptor according to claim 23, in which said projecting part (32) is a pin.

25. Susceptor according to claim 24, in which said pin comprises a shank (321) and a head (322), a first end of the shank (321) being joined to the body (31) and a second end of the shank (321) being joined to the head (322).

26. Susceptor according to claim 25, in which the shank (321) has the shape substantially of a cylinder, in which the head (322) has the shape substantially of a cylinder, in which preferably the diameter of the head is 2 or 3 times the diameter of the shank, and in which preferably the height of the shank is 2 or 3 times the height of the head.

27. Susceptor according to claim 23, in which the body (31) has the shape substantially of a disc.

28. Susceptor according to claim 27, in which the projecting part (32) is situated substantially in the centre of the disc (31).

29. Susceptor according to claim 27, in which the or each recess (311) is situated on one side of the disc (31) and in which the projecting part (32) is situated on said side of the disc (31).

30. Susceptor according to claim 28, in which the or each recess (311) is situated on one side of the disc (31) and in which the projecting part (32) is situated on said side of the disc (31).

31. Susceptor according to claim 23, in which the projecting part (32) forms one piece with the body (31).

32. Susceptor according to claim 23, in which the projecting part (32) is mounted on the body (31).

33. Susceptor according to claim 23, in which the body (31) is made of electrically conductive material, preferably graphite.

34. Susceptor according to claim 33, in which the body (31) is coated with a layer of inert and refractory material, preferably SiC or TaC.

35. Susceptor according to claim 23, in which the projecting part (32) is made of electrically conductive material, preferably graphite.

36. Susceptor according to claim 35, in which the projecting part (32) is coated with a layer of inert and refractory material, preferably SiC or TaC.

37. Susceptor according to claim 34, in which the layers coating the body (31) and the projecting part (32) are formed after mounting the projecting part (32) on the body (31).

38. Tool (9) specifically designed to grip a projecting part (32) of a susceptor (3), the susceptor comprising a body (31) provided typically with at least one recess (311) for housing substrates on which epitaxial growth is to be performed, characterized in that it comprise a projecting part (32) able to be gripped by a tool (9) so as to be introduced into and extracted from a reaction chamber (12) of an epitaxial reactor according to claim 23.

39. Tool according to claim 38, comprising means for mounting or engagement thereof on the arm of a robot.

40. Tool according to claim 38, comprising a bar (91) which, at one of its ends, has a slot (92).

41. Tool according to claim 40, in which, at said end, the bar (91) has a substantially rectangular cross-section, in which the width of the bar (91) is preferably 3 to 9 times the thickness of the bar (91) and in which the width of the slot (92) is preferably 1 to 3 times the thickness of the bar (91).

42. Tool according to claim 40, in which the bar (91) has at least one recess (93) along said slot (92).

43. Tool according to claim 41, in which the bar (91) has at least one recess (93) along said slot (92).

44. Tool according to claim 40, in which the bar (91) is made of metal, preferably stainless steel, or a non-metallic material, preferably quartz.

45. Epitaxial reactor comprising a susceptor (3) having a body (31) provided typically with at least one recess (311) for housing substrates on which epitaxial growth is to be performed, characterized in that it comprise a projecting part (32) able to be gripped by a tool (9) so as to be introduced into and extracted from a reaction chamber (12) of an epitaxial reactor.

46. Epitaxial reactor according to claim 45, comprising means (5) able to heat the susceptor (3) by means of electromagnetic induction.
